(19) United States
(12) Patent Application Publication
(10) Pub. No.: US 2025/0079254 A1
(43) Pub. Date: Mar. 6, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Po-Yuan SU, Taichung City (TW); Chi-Ching HO, Taichung City (TW); Chao-Chiang PU, Taichung City (TW); Yi-Min FU, Taichung City (TW); Che-Yu LEE, Taichung City (TW)

(21) Appl. No.: 18/404,479

(22) Filed: Jan. 4, 2024

(30) Foreign Application Priority Data
Aug. 30, 2023 (TW) 112132835

(51) Int. Cl. H01L 23/367; H01L 23/00; H01L 23/31; H01L 23/498; H01L 25/065

(52) U.S. Cl. CPC H01L 23/3675; H01L 23/3128; H01L 23/49816; H01L 24/08; H01L 24/16; H01L 25/0652; H01L 2224/08146; H01L 2224/08225; H01L 2224/16146; H01L 2224/16227; H01L 2924/01029; H01L 2924/014; H01L 2924/15311; H01L 2924/182

(57) ABSTRACT

An electronic package is provided and includes: a thermally conductive chip; a circuit structure having a circuit layer; and an electronic component disposed between the circuit structure and the thermally conductive chip and electrically connected to the circuit layer, so as to dissipate the heat generated during the operation of the electronic component via the thermally conductive chip. A method of manufacturing the electronic package is further provided.

### BACKGROUND

### 1. Technical Field

The present disclosure relates to a semiconductor device, and more particularly, to an electronic package and a manufacturing method thereof.

### 2. Description of Related Art

As the demand for functionality and processing speed of electronic products increases, a semiconductor chip, which is used as a core assembly of an electronic product, needs electronic components and electronic circuits with higher density. This means that the semiconductor chip will generate a greater amount of heat energy during operation.

In order to quickly dissipate heat energy into the atmosphere, as shown in FIG. 1, the manufacturing method of a conventional semiconductor package 1 is to firstly place a semiconductor chip 11 on a package substrate 10, and then form an encapsulation layer 12 on the package substrate 10 to cover the semiconductor chip 11. Next, a heat dissipation member 14 (a heat sink or a heat spreader) is bonded onto the semiconductor chip 11 and the encapsulation layer 12 (with poor heat conduction effect) via a heat conduction layer 13, so as to dissipate the heat energy generated by the semiconductor chip 11 via the heat conduction layer 13 and the heat dissipation member 14, wherein the heat conduction layer 13 may be made of a thermal interface material (TIM) or a backside metal. In addition, a plurality of conductive elements 15 can be disposed under the package substrate 10 to be connected to an external circuit board. However, although a good heat dissipation effect can be obtained when the heat conduction layer 13 is formed on a composite surface composed of the semiconductor chip 11 and the encapsulation layer 12, the heat dissipation member 14 is disposed on the package substrate 10, and the plurality of conductive elements 15 are provided on the lower side of the package substrate 10, so that the electrical performance of the semiconductor package 1 is limited by the number of chips between the heat dissipation member 14 and the conductive elements 15.

Therefore, how to take into account the good heat dissipation of the semiconductor package 1 and increase the electrical performance of the semiconductor package 1 to meet future product requirements has become an urgent issue in the industry.

### SUMMARY

In view of the various deficiencies of the prior art, the present disclosure provides an electronic package, which comprises: a circuit structure having a circuit layer and a first side and a second side opposing the first side; an electronic component disposed on the first side of the circuit structure and electrically connected to the circuit layer; and a thermally conductive chip disposed on the electronic component, wherein the electronic component is sandwiched between the circuit structure and the thermally conductive chip.

In the aforementioned electronic package, the present disclosure further comprises a plurality of conductive pillars disposed between the first side of the circuit structure and the thermally conductive chip and electrically connected to the circuit layer.

In the aforementioned electronic package, the thermally conductive chip has a plurality of conductive vias, and the plurality of conductive vias are electrically connected to the circuit layer via the plurality of conductive pillars.

In the aforementioned electronic package, the electronic component is disposed on the first side of the circuit structure via a plurality of conductive bumps.

In the aforementioned electronic package, the present disclosure further comprises an encapsulation layer formed between the first side of the circuit structure and the thermally conductive chip and covering the electronic component and the plurality of conductive pillars.

In the aforementioned electronic package, the electronic component is disposed on the first side of the circuit structure via a plurality of conductive bumps, and an underfill covering the plurality of conductive bumps is further formed between the electronic component and the first side of the circuit structure.

In the aforementioned electronic package, the electronic component is disposed on the first side of the circuit structure via a plurality of conductive bumps, and an encapsulation layer covering the plurality of conductive bumps, the electronic component and the plurality of conductive pillars is formed between the thermally conductive chip and the first side of the circuit structure.

In the aforementioned electronic package, the present disclosure further comprises at least one functional component and at least one conductive component disposed on the second side of the circuit structure.

In the aforementioned electronic package, the present disclosure further comprises a heat dissipation material formed between the thermally conductive chip and the electronic component.

In the aforementioned electronic package, the present disclosure further comprises at least one functional component disposed on the thermally conductive chip.

The present disclosure further provides a method of manufacturing an electronic package, the method comprises: providing a thermally conductive chip, an electronic component and a circuit structure, wherein the circuit structure has a circuit layer and a first side and a second side opposing the first side; and disposing the electronic component between the first side of the circuit structure and the thermally conductive chip, wherein the electronic component is electrically connected to the circuit layer.

In the aforementioned method, the thermally conductive chip has a plurality of conductive vias.

In the aforementioned method, the present disclosure further comprises forming a plurality of conductive pillars on the thermally conductive chip, wherein the plurality of conductive pillars are electrically connected to the plurality of conductive vias.

In the aforementioned method, the electronic component is first disposed on the first side of the circuit structure via a plurality of conductive bumps, and then the plurality of conductive pillars are disposed on the first side of the circuit structure to electrically connect the circuit layer, and at the same time, the thermally conductive chip is bonded onto the electronic component.

In the aforementioned method, the present disclosure further comprises forming an underfill between the electronic component and the first side of the circuit structure to cover the plurality of conductive bumps.

In the aforementioned method, the present disclosure further comprises forming an encapsulation layer between the first side of the circuit structure and the thermally conductive chip to cover the electronic component, the plurality of conductive pillars and the underfill.

In the aforementioned method, the electronic component formed with a plurality of conductive bumps is disposed on the thermally conductive chip.

In the aforementioned method, the present disclosure further comprises forming an encapsulation layer on the thermally conductive chip to cover the electronic component, the plurality of conductive pillars and the plurality of conductive bumps, wherein end surfaces of the plurality of conductive pillars and end surfaces of the plurality of conductive bumps are exposed from the encapsulation layer.

In the aforementioned method, the plurality of conductive pillars and the plurality of conductive bumps are disposed on the first side of the circuit structure, and the circuit layer is electrically connected to the plurality of conductive pillars and the plurality of conductive bumps.

In the aforementioned method, the present disclosure further comprises arranging at least one functional component and at least one conductive component on the second side of the circuit structure.

In the aforementioned method, the thermally conductive chip and the electronic component have a heat dissipation material formed therebetween.

In the aforementioned method, at least one functional component is disposed on the thermally conductive chip.

To sum up, in the electronic package and the manufacturing method thereof of the present disclosure, the thermally conductive chip is stacked on the encapsulation layer and the electronic component, so as to increase the heat dissipation effect of the electronic component. Further, other chips can be connected to the thermally conductive chip to increase the electrical performance of the electronic package. In addition, the electronic package and the manufacturing method thereof of the present disclosure can be completed with existing manufacturing processes, machines and materials, without spending a lot of extra cost, and can take into account both the heat dissipation requirements and the electrical performance.

### BRIEF DESCRIPTION OF THE DRAWINGS

FIG. 1 is a schematic cross-sectional view of a conventional semiconductor package.

FIG. 2A, FIG. 2B, FIG. 2C and FIG. 2D are schematic cross-sectional views illustrating a manufacturing method of an electronic package according to the present disclosure.

FIG. 3A, FIG. 3B, FIG. 3C and FIG. 3D are schematic cross-sectional views illustrating a manufacturing method of an electronic package according to another embodiment of the present disclosure.

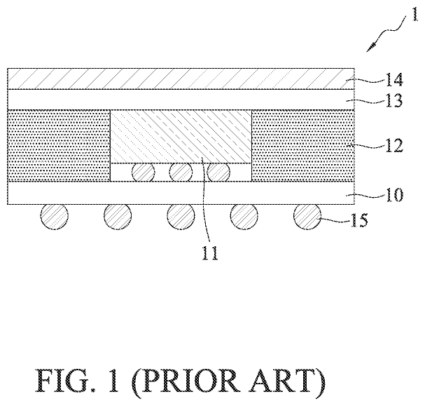

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second” and the like are merely used for clear explanation rather than limiting the practicable scope of the present disclosure, and thus, alterations or adjustments of the relative relationships thereof without essentially altering the technical contents should still be considered in the practicable scope of the present disclosure.

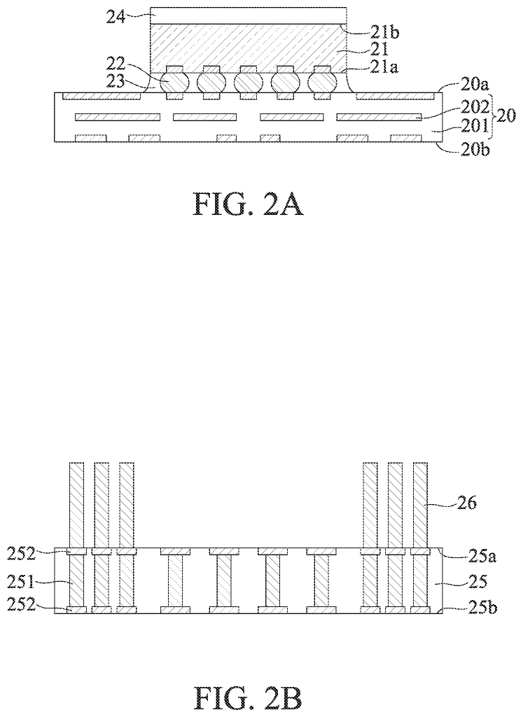

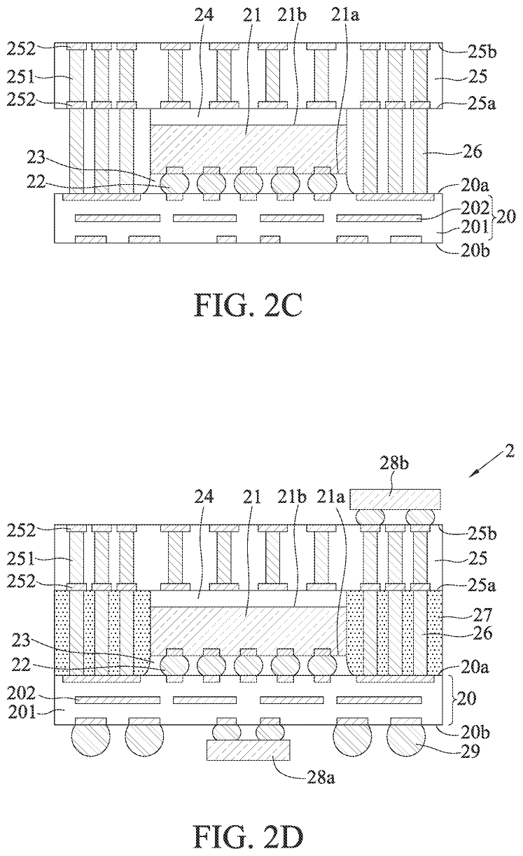

FIG. 2A, FIG. 2B, FIG. 2C and FIG. 2D are schematic cross-sectional views illustrating a manufacturing method of an electronic package 2 of the present disclosure.

As shown in FIG. 2A, a circuit structure 20 and at least one electronic component 21 are provided, and the electronic component 21 is disposed on the circuit structure 20.

The circuit structure 20 has a first side 20a and a second side 20b opposing the first side 20a, and includes at least one dielectric layer 201 and a circuit layer 202 bonded to the dielectric layer 201. For example, a material forming the circuit layer 202 may be copper, and a material forming the dielectric layer 201 may be polybenzoxazole (PBO), polyimide (PI), prepreg (PP), or other dielectric materials, wherein the circuit layer 202 and the dielectric layer 201 can be formed using a redistribution layer (RDL) process.

The electronic component 21 can be an active component, a passive component or a combination of the active component and the passive component, wherein the active component is, for example, a semiconductor chip, and the passive component is, for example, a resistor, a capacitor, or an inductor. In one embodiment, the electronic component 21 is a semiconductor chip, which has an active surface 21a and an inactive surface 21b opposing the active surface 21a.

In one embodiment, a plurality of conductive bumps 22 such as copper pillars, solder balls, etc. can be formed on the active surface 21a of the electronic component 21, and a heat dissipation material 24 is formed on the inactive surface 21b of the electronic component 21, wherein the heat dissipation material 24 is, for example, a thermal interface material (TIM) or a backside metal, such as a high thermal conductivity metal glue material, a solder material, or a metal material (which can be a multi-layer metal material). Next, the electronic component 21 is bonded onto the first side 20a of the circuit structure 20 via the plurality of conductive bumps 22 in a flip-chip manner, so that the electronic component 21 is electrically connected to the circuit layer 202. Afterward, an underfill 23 is formed between the electronic component 21 and the first side 20a of the circuit structure 20 to cover the conductive bumps 22.

As shown in FIG. 2B, a thermally conductive chip 25 is also provided. The thermally conductive chip 25 has a first side 25a and a second side 25b opposing the first side 25a, and includes a plurality of conductive vias 251 and a plurality of pad portions 252, wherein each of the conductive vias 251 may be a conductive through-silicon via (TSV) penetrating through the thermally conductive chip 25, and the pad portions 252 are respectively formed on the first side 25a and the second side 25b, wherein some of the plurality of pad portions 252 are connected to opposite ends of the conductive vias 251. Next, a plurality of conductive pillars 26 (such as copper pillars) are formed on the plurality of pad portions 252 on the first side 25a of the thermally conductive chip 25, wherein the plurality of conductive pillars 26 are electrically connected to the plurality of conductive vias 251.

In one embodiment, the thermally conductive chip 25 is a silicon base thermal die, which may or may not have electrical functions. In addition, non-electrical thermally conductive through-silicon vias (not shown) can also be arranged in the thermally conductive chip 25, and the non-electrical thermally conductive through-silicon vias are only used for connecting the conductive pillars 26 for thermal conduction.

It should be understood that the process shown in FIG. 2A and the process shown in FIG. 2B are not sequential, wherein the process of FIG. 2A or the process of FIG. 2B can be performed first according to requirements, or the processes of FIG. 2A and FIG. 2B are performed concurrently.

As shown in FIG. 2C, the plurality of conductive pillars 26 and the thermally conductive chip 25 are disposed on the first side 20a of the circuit structure 20, wherein the plurality of conductive pillars 26 are electrically connected to the circuit layer 202, and at the same time, the heat dissipation material 24 is provided between the first side 25a of the thermally conductive chip 25 and the inactive surface 21b of the electronic component 21 to increase the heat conduction effect.

As shown in FIG. 2D, an encapsulation layer 27 is formed between the first side 20a of the circuit structure 20 and the first side 25a of the thermally conductive chip 25 to cover the electronic component 21, the plurality of conductive pillars 26, the underfill 23 and the heat dissipation material 24. In one embodiment, a material forming the encapsulation layer 27 is an insulating material, such as an encapsulating glue of epoxy resin. Afterward, at least one first functional component 28a (such as an active chip or a passive component) and a plurality of conductive components 29 (such as solder balls) electrically connected to the circuit layer 202 can be disposed on the second side 20b of the circuit structure 20. Further, at least one second functional component 28b can be optionally connected to the second side 25b of the thermally conductive chip 25 to improve the electrical function (such as an active chip or a passive component), thereby obtaining the electronic package 2 of the present disclosure. Moreover, in subsequent processes, the electronic package 2 can be connected to an electronic device (not shown) such as a circuit board via the plurality of conductive components 29.

In one embodiment, the process of forming the heat dissipation material 24 on the inactive surface 21b of the electronic component 21 in FIG. 2A can be omitted. At this time, in the process of FIG. 2C, the first side 25a of the thermally conductive chip 25 will be directly attached onto the inactive surface 21b of the electronic component 21 (not shown).

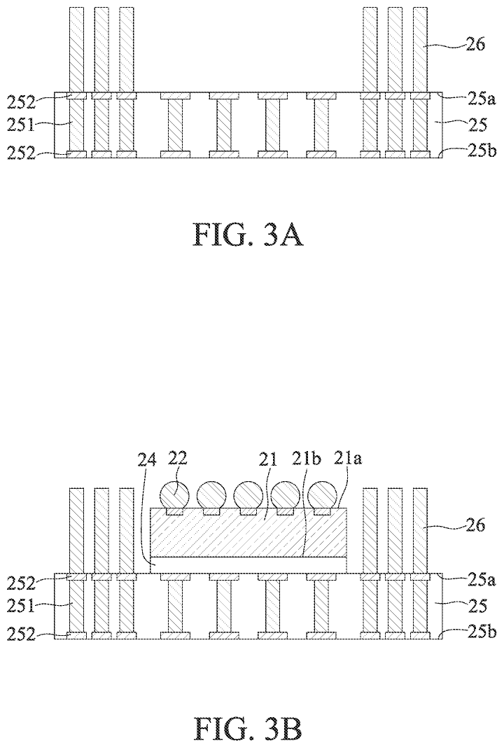

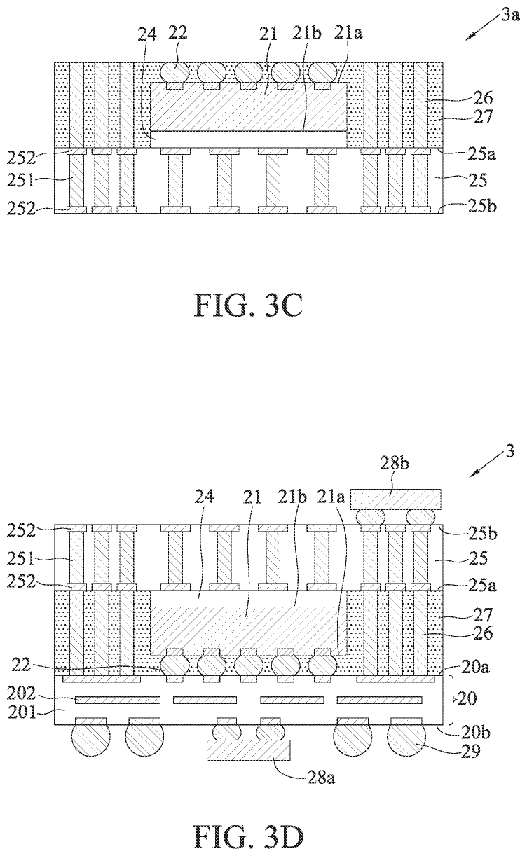

FIG. 3A, FIG. 3B, FIG. 3C and FIG. 3D are schematic cross-sectional views illustrating a manufacturing method of an electronic package 3 according to another embodiment of the present disclosure. The technical contents described in FIG. 3A, FIG. 3B, FIG. 3C and FIG. 3D that are the same as the technical contents described in FIG. 2A, FIG. 2B, FIG. 2C and FIG. 2D will not be repeated.

As shown in FIG. 3A, a thermally conductive chip 25 is provided. The thermally conductive chip 25 has a first side 25a and a second side 25b opposing the first side 25a, and includes a plurality of conductive vias 251 (such as conductive through-silicon vias [TSVs]) and a plurality of pad portions 252, wherein the plurality of conductive vias 251 penetrate through the thermally conductive chip 25, the plurality of pad portions 252 are respectively formed on the first side 25a and the second side 25b, and some of the plurality of pad portions 252 are connected to opposite ends of the conductive vias 251. Next, a plurality of conductive pillars 26 (such as copper pillars) are formed on the plurality of pad portions 252 on the first side 25a of the thermally conductive chip 25, wherein the plurality of conductive pillars 26 are electrically connected to the plurality of conductive vias 251. In addition, non-electrical thermally conductive through-silicon vias (not shown) can also be arranged in the thermally conductive chip 25, and the non-electrical thermally conductive through-silicon vias are only used for connecting the conductive pillars 26 for thermal conduction.

As shown in FIG. 3B, an electronic component 21 having an active surface 21a and an inactive surface 21b opposing the active surface 21a is provided, wherein a plurality of conductive bumps 22 such as copper pillars and solder balls are formed on the active surface 21a, and a heat dissipation material 24 is formed on the inactive surface 21b, and wherein the heat dissipation material 24 is a thermal interface material (TIM) or backside metal, such as a high thermal conductivity metal glue material, a solder material, or a metal material (which can be a multi-layer metal material). In one embodiment, the electronic component 21 is connected onto the first side 25a of the thermally conductive chip 25 via the heat dissipation material 24.

In one embodiment, the process of forming the heat dissipation material 24 on the inactive surface 21b of the electronic component 21 can also be omitted. At this time, the inactive surface 21b of the electronic component 21 will be attached to the first side 25a of the thermally conductive chip 25.

As shown in FIG. 3C, an encapsulation layer 27 is formed on the first side 25a of the thermally conductive chip 25 and the active surface 21a of the electronic component 21 to cover the electronic component 21, the plurality of conductive pillars 26, the plurality of conductive bumps 22 and the heat dissipation material 24, so as to form a package module 3a. In one embodiment, a material forming the encapsulation layer 27 is an insulating material, such as an encapsulating glue of epoxy resin, and the encapsulation layer 27 can be formed by molding, lamination, or coating.

Furthermore, the encapsulation layer 27 can first completely cover the plurality of conductive bumps 22 and the plurality of conductive pillars 26, and then a leveling process is performed on a top surface of the encapsulation layer 27 by grinding or other methods, so that end surfaces of the plurality of conductive bumps 22 and end surfaces of the plurality of conductive pillars 26 are exposed from the encapsulation layer 27.

As shown in FIG. 3D, a circuit structure 20 is also provided, wherein the circuit structure 20 has a first side 20a and a second side 20b opposing the first side 20a, and includes at least one dielectric layer 201 and a circuit layer 202 bonded to the dielectric layer 201. In one embodiment, the package module 3a is disposed on the first side 20a of the circuit structure 20, and the plurality of conductive pillars 26 and the plurality of conductive bumps 22 are electrically connected to the circuit layer 202. Afterward, at least one first functional component 28a (such as an active chip or a passive component) and a plurality of conductive components 29 (such as solder balls) electrically connected to the circuit layer 202 can be disposed on the second side 20b of the circuit structure 20. Further, at least one second functional component 28b can be optionally connected to the second side 25b of the thermally conductive chip 25 to improve the electrical function, thereby obtaining the electronic package 3 of the present disclosure. Moreover, in subsequent processes, the electronic package 3 can be connected onto an electronic device (not shown) such as a circuit board via the plurality of conductive components 29. Another way to manufacture the structure of FIG. 3D is to perform a leveling process on the top surface of the encapsulation layer 27 in FIG. 3C by means of grinding and the like, and then continue to form the stacked dielectric layer 201 and the circuit layer 202 one by one by a patterning process to form the circuit structure 20.

The present disclosure further provides an electronic package 2, 3, which comprises a circuit structure 20, an electronic component 21, a plurality of conductive bumps 22, a thermally conductive chip 25, a plurality of conductive pillars 26, an encapsulation layer 27, at least one functional component (such as a first functional component 28a and a second functional component 28b) and a plurality of conductive components 29.

The circuit structure 20 has a first side 20a and a second side 20b opposing the first side 20a, and includes at least one dielectric layer 201 and a circuit layer 202 bonded to the dielectric layer 201.

The electronic component 21 has an active surface 21a and an inactive surface 21b opposing the active surface 21a, wherein the plurality of conductive bumps 22 such as copper pillars and solder balls are formed on the active surface 21a, and a heat dissipation material 24 is formed on the inactive surface 21b. The electronic component 21 is bonded onto the first side 20a of the circuit structure 20 via the plurality of conductive bumps 22 in a flip-chip manner, so that the electronic component 21 is electrically connected to the circuit layer 202. In one embodiment, forming the heat dissipation material 24 on the inactive surface 21b can be omitted.

The thermally conductive chip 25 may be a silicon base thermal die, which has a first side 25a and a second side 25b opposing the first side 25a, and includes a plurality of conductive vias 251 and a plurality of pad portions 252, wherein the plurality of conductive vias 251 penetrate through the thermally conductive chip 25, and the plurality of pad portions 252 are respectively formed on the first side 25a and the second side 25b and connected to opposite ends of the conductive vias 251. The first side 25a of the thermally conductive chip 25 is disposed on the inactive surface 21b of the electronic component 21 via the heat dissipation material 24. In addition, the heat dissipation material 24 can be omitted, so that the first side 25a of the thermally conductive chip 25 is disposed on the inactive surface 21b of the electronic component 21.

The plurality of conductive pillars 26 are formed between the first side 20a of the circuit structure 20 and the first side 25a of the thermally conductive chip 25, and are electrically connected to the circuit layer 202 and the plurality of pad portions 252, so that the plurality of conductive vias 251 are electrically connected to the circuit layer 202 via the plurality of conductive pillars 26.

The encapsulation layer 27 is formed between the first side 20a of the circuit structure 20 and the first side 25a of the thermally conductive chip 25 to cover the electronic component 21 and the plurality of conductive pillars 26.

In one embodiment, an underfill 23 covering the plurality of conductive bumps 22 is formed between the active surface 21a of the electronic component 21 and the first side 20a of the circuit structure 20, and the encapsulation layer 27 also covers the underfill 23 at the same time.

In another embodiment, no underfill 23 is formed between the active surface 21a of the electronic component 21 and the first side 20a of the circuit structure 20, but the encapsulation layer 27 is formed, so that the encapsulation layer 27 can cover the plurality of conductive bumps 22 at the same time.

The first functional component 28a (such as an active chip or a passive component) and the plurality of conductive components 29 (such as solder balls) can be arranged on the second side 20b of the circuit structure 20 and electrically connected to the circuit layer 202 for connection to an electronic device such as a circuit board. In addition, at least one second functional component 28b can be connected to the second side 25b of the thermally conductive chip 25 to improve the electrical function.

To sum up, in the electronic package and the manufacturing method thereof of the present disclosure, the thermally conductive chip is stacked on the encapsulation layer and the electronic component, so that the heat generated by the operation of the electronic component can be transferred to the outside via the thermally conductive chip (such as the conductive vias), thereby increasing the heat dissipation effect of the electronic component. Further, other chips can be connected onto the thermally conductive chip to increase the electrical performance of the electronic package. In addition, the electronic package and the manufacturing method thereof of the present disclosure can be completed with existing manufacturing processes, machines and materials, without spending a lot of extra cost, and can take into account both the heat dissipation requirements and the electrical performance.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a circuit structure having a circuit layer and a first side and a second side opposing the first side;
an electronic component disposed on the first side of the circuit structure and electrically connected to the circuit layer; and
a thermally conductive chip disposed on the electronic component, wherein the electronic component is sandwiched between the circuit structure and the thermally conductive chip.

2. The electronic package of claim 1, further comprising a plurality of conductive pillars disposed between the first side of the circuit structure and the thermally conductive chip and electrically connected to the circuit layer.

3. The electronic package of claim 2, wherein the thermally conductive chip has a plurality of conductive vias, and the plurality of conductive vias are electrically connected to the circuit layer via the plurality of conductive pillars.

4. The electronic package of claim 1, wherein the electronic component is disposed on the first side of the circuit structure via a plurality of conductive bumps.

5. The electronic package of claim 2, further comprising an encapsulation layer formed between the first side of the circuit structure and the thermally conductive chip and covering the electronic component and the plurality of conductive pillars.

6. The electronic package of claim 1, wherein the electronic component is disposed on the first side of the circuit structure via a plurality of conductive bumps, and an underfill covering the plurality of conductive bumps is further formed between the electronic component and the first side of the circuit structure.

7. The electronic package of claim 2, wherein the electronic component is disposed on the first side of the circuit structure via a plurality of conductive bumps, and an encapsulation layer covering the plurality of conductive bumps, the electronic component and the plurality of conductive pillars is formed between the thermally conductive chip and the first side of the circuit structure.

8. The electronic package of claim 1, further comprising at least one functional component and at least one conductive component disposed on the second side of the circuit structure.

9. The electronic package of claim 1, further comprising a heat dissipation material formed between the thermally conductive chip and the electronic component.

10. The electronic package of claim 1, further comprising at least one functional component disposed on the thermally conductive chip.

11. A method of manufacturing an electronic package, comprising:
providing a thermally conductive chip, an electronic component and a circuit structure, wherein the circuit structure has a circuit layer and a first side and a second side opposing the first side; and
disposing the electronic component between the first side of the circuit structure and the thermally conductive chip, wherein the electronic component is electrically connected to the circuit layer.

12. The method of claim 11, wherein the thermally conductive chip has a plurality of conductive vias.

13. The method of claim 12, further comprising forming a plurality of conductive pillars on the thermally conductive chip, wherein the plurality of conductive pillars are electrically connected to the plurality of conductive vias.

14. The method of claim 13, wherein the electronic component is first disposed on the first side of the circuit structure via a plurality of conductive bumps, and then the plurality of conductive pillars are disposed on the first side of the circuit structure to electrically connect the circuit layer, and at the same time, the thermally conductive chip is bonded onto the electronic component.

15. The method of claim 14, further comprising forming an underfill between the electronic component and the first side of the circuit structure to cover the plurality of conductive bumps.

16. The method of claim 15, further comprising forming an encapsulation layer between the first side of the circuit structure and the thermally conductive chip to cover the electronic component, the plurality of conductive pillars and the underfill.

17. The method of claim 13, wherein the electronic component formed with a plurality of conductive bumps is disposed on the thermally conductive chip.

18. The method of claim 17, further comprises forming an encapsulation layer on the thermally conductive chip to cover the electronic component, the plurality of conductive pillars and the plurality of conductive bumps, wherein end surfaces of the plurality of conductive pillars and end surfaces of the plurality of conductive bumps are exposed from the encapsulation layer.

19. The method of claim 18, wherein the plurality of conductive pillars and the plurality of conductive bumps are disposed on the first side of the circuit structure, and the circuit layer is electrically connected to the plurality of conductive pillars and the plurality of conductive bumps.

20. The method of claim 11, further comprising arranging at least one functional component and at least one conductive component on the second side of the circuit structure.

21. The method of claim 11, wherein the thermally conductive chip and the electronic component have a heat dissipation material formed therebetween.

22. The method of claim 11, wherein at least one functional component is disposed on the thermally conductive chip.
